(19) United States
(12) Patent Application Publication
(10) Pub. No.: US 2026/0122981 A1
(43) Pub. Date: Apr. 30, 2026

(54) SEMICONDUCTOR DEVICE

(71) Applicant: FUJI ELECTRIC CO., LTD., Kawasaki-shi, Kanagawa (JP)

(72) Inventor: Chansoon KOO, Matsumoto-city, Nagano (JP)

(73) Assignee: FUJI ELECTRIC CO., LTD., Kawasaki-shi, Kanagawa (JP)

(21) Appl. No.: 19/313,833

(22) Filed: Aug. 28, 2025

(30) Foreign Application Priority Data
Oct. 24, 2024 (JP) 2024-187810

(51) Int. Cl. H10D 62/10

(52) U.S. Cl. CPC H10D 62/106

(57) ABSTRACT

A semiconductor device, including: a semiconductor substrate having a termination region surrounding an active region in a plan view; a first semiconductor layer, provided on the semiconductor substrate in both the active region and the termination region, and having a dopant concentration lower than the semiconductor substrate; a first semiconductor region, provided in the active region at a first surface of the first semiconductor layer; a plurality of second semiconductor regions provided in the termination region at the first surface of the first semiconductor layer, the second semiconductor regions being formed at intervals surrounding the first semiconductor region in the plan view; and a plurality of third semiconductor regions respectively provided in a subset of the second semiconductor regions adjacent to the first semiconductor region, each third semiconductor region being at a surface of the respective second semiconductor region and being at a center thereof in the plan view.

### CROSS REFERENCE TO RELATED APPLICATIONS

This application is based upon and claims the benefit of priority of the prior Japanese Patent Application No. 2024-187810, filed on Oct. 24, 2024, the entire contents of which are incorporated herein by reference.

### BACKGROUND OF THE INVENTION

### 1. Field of the Invention

Embodiments of the disclosure relate to a semiconductor device.

### 2. Description of the Related Art

Conventionally, a semiconductor device has been proposed in which guard rings are provided at a constant pitch in an edge termination portion and an embedded injection layer 30 connected to bottoms of the guard rings is provided (for example, refer to Japanese Patent No. 5676002).

### SUMMARY OF THE INVENTION

According to an embodiment of the present disclosure, a semiconductor device, includes: a semiconductor substrate of a first conductivity type, the semiconductor substrate having: an active region through which a main current flows, and a termination region surrounding a periphery of the active region in a plan view of the semiconductor device; a first semiconductor layer of the first conductivity type, provided on the semiconductor substrate in both the active region and the termination region, the first semiconductor layer having a dopant concentration lower than a dopant concentration of the semiconductor substrate, the first semiconductor layer having a first surface and a second surface opposite to each other, the second surface facing the semiconductor substrate; a first semiconductor region of a second conductivity type, provided in the active region at the first surface of the first semiconductor layer; a plurality of second semiconductor regions of the second conductivity type, provided in the termination region at the first surface of the first semiconductor layer, the plurality of second semiconductor regions being formed at intervals and each in a ring-shape surrounding the first semiconductor region in the plan view; and a plurality of third semiconductor regions of the first conductivity type, respectively provided in a subset of the plurality of second semiconductor regions adjacent to an end of the first semiconductor region, each third semiconductor region being provided at a surface of the respective second semiconductor region and being at a center thereof in the plan view.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a top view of a silicon carbide semiconductor device according to an embodiment.

FIG. 2 is an enlarged view of a region Z of the silicon carbide semiconductor device according to the embodiment depicted in FIG. 1.

FIG. 3 is a cross-sectional view of an edge termination structure of the silicon carbide semiconductor device according to the embodiment, along cutting line A-A′.

FIG. 4A is a cross-sectional view of an active structure of the silicon carbide semiconductor device according to the embodiment, along cutting line B-B′.

FIG. 4B is a cross-sectional view of the active structure of the silicon carbide semiconductor device according to the embodiment, along cutting line C-C′.

FIG. 4C is a cross-sectional view of the active structure of the silicon carbide semiconductor device according to the embodiment, along cutting line D-D′.

FIG. 5A is graph depicting distribution of an AI concentration of FLRs of a conventional silicon carbide semiconductor device, in a depth direction.

FIG. 5B is a graph depicting distribution of an AI concentration in FLRs of the silicon carbide semiconductor device according to the embodiment, in a depth direction.

FIG. 6A is a graph depicting an edge breakdown voltage of the conventional silicon carbide semiconductor device and the silicon carbide semiconductor device according to the embodiment.

FIG. 6B is a graph showing edge surface horizontal electric field strength of the conventional silicon carbide semiconductor device and the silicon carbide semiconductor device according to the embodiment.

FIG. 7A is a graph depicting the edge breakdown voltage in an instance in which doses of the FLRs of the conventional silicon carbide semiconductor device and the silicon carbide semiconductor device according to the embodiment are each +10%.

FIG. 7B is a graph depicting edge-surface horizontal electric field strength in an instance in which the doses of the FLRs of the conventional silicon carbide semiconductor device and the silicon carbide semiconductor device according to the embodiment are each +10%.

FIG. 8A is a graph depicting the edge breakdown voltage in an instance in which the doses of the FLRs of the conventional silicon carbide semiconductor device and the silicon carbide semiconductor device according to the embodiment are each −10%.

FIG. 8B is a graph depicting edge-surface horizontal electric field strength in an instance in which the doses of the FLRs of the conventional silicon carbide semiconductor device and the silicon carbide semiconductor device according to the embodiment are each −10%.

FIG. 9A is a graph depicting the edge breakdown voltage in an instance in which widths of the FLRs of the conventional silicon carbide semiconductor device and the silicon carbide semiconductor device according to the embodiment are each increased 0.3 μm.

FIG. 9B is a graph depicting edge-surface horizontal electric field strength in an instance in which the widths of the FLRs of the conventional silicon carbide semiconductor device and the silicon carbide semiconductor device according to the embodiment are each increased 0.3 μm.

FIG. 10A is a graph depicting the edge breakdown voltage in an instance in which the widths of the FLRs of the conventional silicon carbide semiconductor device and the silicon carbide semiconductor device according to the embodiment are each decreased 0.3 μm.

FIG. 10B is a graph depicting edge-surface horizontal electric field strength in an instance in which the widths of the FLRs of the conventional silicon carbide semiconductor device and the silicon carbide semiconductor device according to the embodiment are each decreased 0.3 μm.

FIG. 11 is a graph depicting edge-surface electric field distribution in the conventional silicon carbide semiconductor device and the silicon carbide semiconductor device according to the embodiment.

FIG. 12 is a top view of a conventional silicon carbide semiconductor device.

FIG. 13 is an enlarged view of a region Z of the conventional silicon carbide semiconductor device depicted in FIG. 12.

FIG. 14 is a cross-sectional view of an edge termination structure of the conventional silicon carbide semiconductor device, along cutting line A-A′.

FIG. 15A is a cross-sectional view of an active structure of the conventional silicon carbide semiconductor device, along cutting line B-B′.

FIG. 15B is a cross-sectional view of the active structure of the conventional silicon carbide semiconductor device, along cutting line C-C′.

FIG. 15C is a cross-sectional view of the active structure of the conventional silicon carbide semiconductor device, along cutting line D-D′.

### DETAILED DESCRIPTION OF THE INVENTION

First problems associated with the conventional techniques are discussed. With a conventional field limiting ring (FLR) structure configured by guard rings, a problem arises in that the breakdown voltage varies greatly due to variations in dimensions and edge surface charge.

An outline of an embodiment of the present disclosure is described. A semiconductor device according to the present disclosure solving the problems described above and achieving an object has the following features. The semiconductor device has, on a semiconductor substrate of a first conductivity type, an active region through which a main current flows and a termination region surrounding a periphery of the active region. The semiconductor device has, in the active region, a first semiconductor layer of the first conductivity type, provided on the semiconductor substrate and having a dopant concentration lower than that of the semiconductor substrate, and a first semiconductor region of a second conductivity type, provided at a first surface of the first semiconductor layer opposite to a second surface thereof facing the semiconductor substrate. The semiconductor device has, in the termination region, the first semiconductor layer, and a plurality of second semiconductor regions of the second conductivity type, provided in intervals and in contact with the surface of the first semiconductor layer. The plurality of second semiconductor regions is provided in ring-shapes so as to surround the first semiconductor region, and a plurality of third semiconductor regions of the first conductivity type is provided, each being provided in a center of each of a predetermined number of the plurality of second semiconductor regions from an end of the first semiconductor region, at a surface of the each of the predetermined number of the plurality of second semiconductor regions.

According to the disclosure above, provision of the third semiconductor regions (intra-FLR n⁻-type regions) that are portions of the first semiconductor layer (n⁻-type drift region) left at the surface of the second semiconductor regions (FLR) relaxes concentration of the electric field. As a result, the breakdown voltage is further improved as compared to the conventional structure, the risk of dielectric breakdown at the edge is reduced, and increases in surface electric field strength when charge accumulates at the edge surface is suppressed and the risk of discharge may be suppressed. Further, in the formation of the FLR and the intra-FLR n-type regions, SiC etching and high-acceleration ion implantation are not used, whereby manufacturing costs may be reduced.

Further, in the semiconductor device according to the present disclosure, in the disclosure above, the plurality of third semiconductor regions is provided within a range of ⅕ or more but not more than ½ of a distance from the surface of the first semiconductor layer to lower surfaces of the plurality of second semiconductor regions.

Further, in the semiconductor device according to the present disclosure, in the disclosure above, each of the plurality of third semiconductor regions is apart from an end of the each of the predetermined number of the plurality of second semiconductor regions by 10% or more but not more than 25% of a width of the each of the plurality of second semiconductor regions.

Further, in the semiconductor device according to the present disclosure, in the disclosure above, a width of the each of the plurality of third semiconductor regions is 50% or more but not more than 80% of a width of the each of the plurality of second semiconductor regions.

Further, in the semiconductor device according to the present disclosure, in the disclosure above, the plurality of third semiconductor regions has a dopant concentration that is 1/10 times or more but not more than 10 times the dopant concentration of the first semiconductor layer at a predetermined position of the plurality of third semiconductor regions.

Further, in the semiconductor device according to the present disclosure, in the disclosure above, the predetermined position of the plurality of third semiconductor regions is a center of a depth of the plurality of third semiconductor regions and a center of a width of the each of the plurality of third semiconductor regions.

Further, in the semiconductor device according to the present disclosure, in the disclosure above, the predetermined position of the plurality of third semiconductor regions is a region 20% inward from both ends of the plurality of third semiconductor regions when a center of a depth of the plurality of third semiconductor regions and a width of the each of the plurality of third semiconductor regions is 100%.

Further, in the semiconductor device according to the present disclosure, in the disclosure above, a dopant concentration of the plurality of third semiconductor regions is higher at surfaces of the plurality of third semiconductor regions than at a center of a depth of the plurality of third semiconductor regions.

Further, in the semiconductor device according to the present disclosure, in the disclosure above, the plurality of third semiconductor regions is provided in the plurality of second semiconductor regions closest to the active region.

Further, in the semiconductor device according to the present disclosure, in the disclosure above, the plurality of third semiconductor regions is provided in ¼ or more of the plurality of second semiconductor regions closest to the active region.

Further, in the semiconductor device according to the present disclosure, in the disclosure above, of the plurality of second semiconductor regions, ones having a width of 1.5 μm or less are free of the plurality of third semiconductor regions.

Further, in the semiconductor device according to the present disclosure, in the disclosure above, the plurality of second semiconductor regions is provided at a depth of 1.0 μm or more but not more than 2.0 μm from the surface of the first semiconductor layer.

Further, in the semiconductor device according to the present disclosure, in the disclosure above, the plurality of second semiconductor regions has a dopant concentration with a maximum value within a range of ½ or more but not more than ¾ of a distance from the surface of the first semiconductor layer to lower surfaces of the plurality of second semiconductor regions.

Further, in the semiconductor device according to the present disclosure, in the disclosure above, the plurality of second semiconductor regions has a floating potential without being electrically connected to an electrode of the semiconductor device.

Findings underlying the present disclosure are discussed. First, problems associated with the conventional semiconductor device are discussed. In the semiconductor device, an edge termination region that has a voltage withstanding structure and that surrounds a periphery of an active region through which a current passes during an on-state is provided. In a power semiconductor device, the voltage withstanding structure is fabricated by forming a p-type structure at a surface of an n-type substrate. In a semiconductor device element (hereinafter, silicon carbide semiconductor device) containing silicon carbide (SiC) as a semiconductor material, a spatial modulation junction termination extension (JTE) structure, a FLR structure, or a structure combining both is mainly used.

The voltage withstanding structure of the edge termination region plays a role in making an edge breakdown voltage equal to or greater than that of the active region by relaxing the concentration of electric field at an end of the active region. As a result, dielectric breakdown is caused to occur in the active region, which has a larger area than that of the edge termination region, whereby the risk of thermal breakdown of the chip is reduced and the impact of charge accumulated at the surface of the edge termination region is reduced, thereby enabling the breakdown voltage to be stabilized.

The spatial modulation JTE structure forms a structural concentration distribution by a patterned p-type region (JTE) to prevent electric field concentration. In the FLR structure, a p-type regions are each disposed in a ring-shape as viewed from the surface, whereby electric field is distributed and the breakdown voltage is obtained. Further, a structure combining a JTE so as to cover the FLR, which is disposed toward the active region, is conceivable.

While the spatial modulation JTE structure may reduce variations in dimensions and the impact of surface charge of the edge termination region, multiple ion implantation sessions in addition to that for a formation process of the active region are necessary and thus, the manufacturing cost increases. Further, in SiC, in which dopant diffusion is difficult, etching of surface SiC or ion implantation with high acceleration energy is required to ensure a depth equivalent to that of the active region, which also leads to an increase in manufacturing costs. Further, in the FLR structure, while ion implantation is completed with one session and formation together with p-type regions of the active region is possible enabling relatively low manufacturing costs, variation of the breakdown voltage due to variations in dimensions and edge surface charge is large.

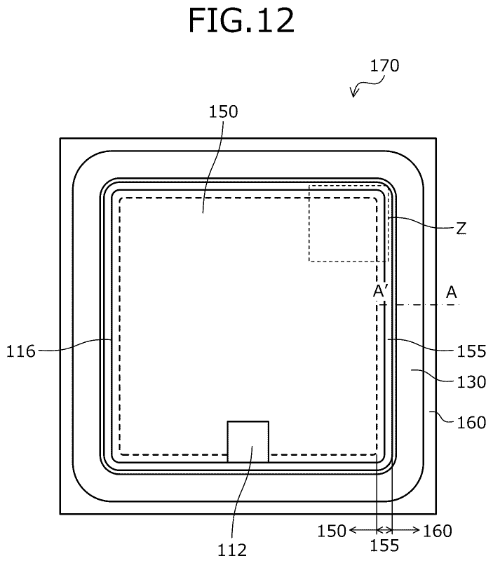

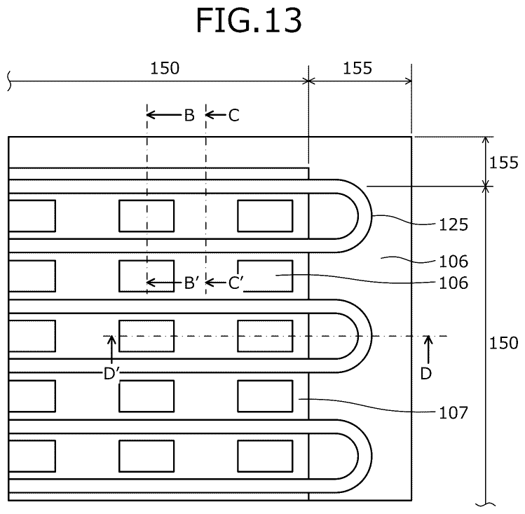

FIG. 12 is a top view of a conventional silicon carbide semiconductor device 170. FIG. 13 is an enlarged view of a region Z of the conventional silicon carbide semiconductor device 170 depicted in FIG. 12.

The silicon carbide semiconductor device 170 in FIG. 12 has an active region 150, an edge termination region 160 surrounding the active region 150 in a plan view, and a border region 155 between the active region 150 and the edge termination region 160. The active region 150 is a region through which current flows during an on-state and the edge termination region 160 is region that relaxes electric field of a front side of an n⁻-type drift region 102 and sustains the breakdown voltage. The border region 155 is a region connecting the active region 150 and the edge termination region 160. In the present example, a FLR structure 130 configured by multiple FLRs 131 so as to surround the border region 155 in a plan view is provided in the edge termination region 160. In the border region 155, gate wiring (not depicted) is provided and connected to a gate pad 112. A region indicated by hatching is a source electrode 116. The source electrode 116 is provided spanning from the active region 150 to the border region 155.

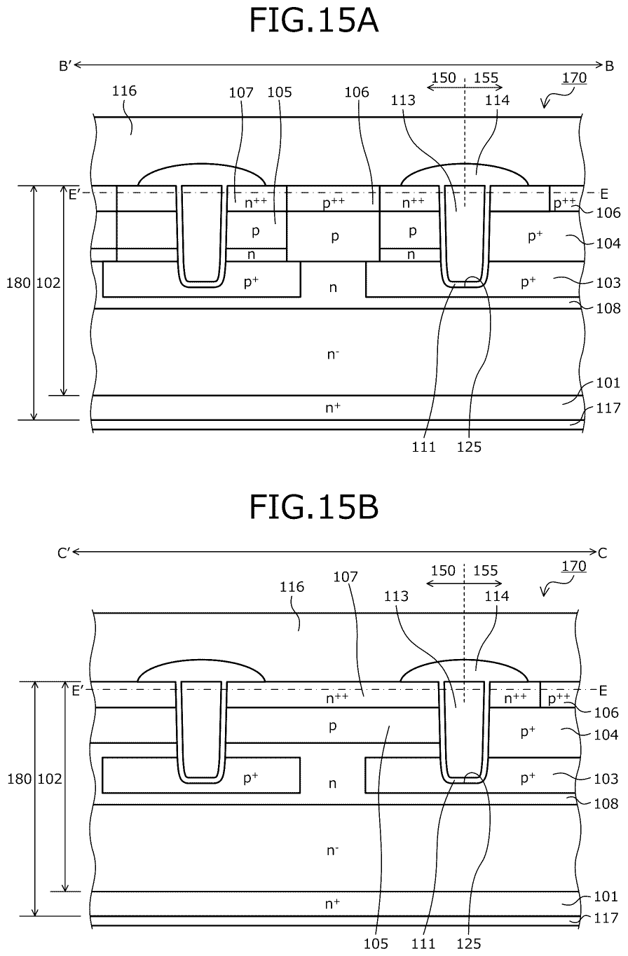

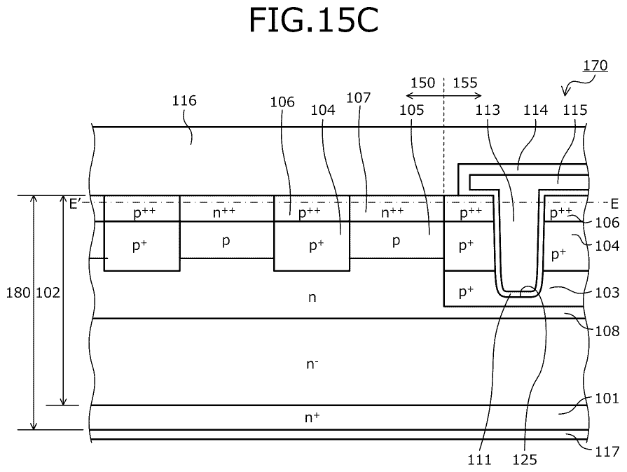

FIG. 13 is an enlarged plan view of the region Z in FIG. 12, at a depth of cutting line E-E′ depicted in later-described FIGS. 15A to 15C. In the active region 150, trenches 125 each provided in a stripe-like shape, gate electrodes 113 provided in the trenches 125 via gate insulating films (not depicted), n⁺⁺-type source regions 107, and p⁺⁺-type contact regions 106 are provided. A border between the active region 150 and the border region 155 in a direction in which the trenches 125 extend is an end of each outermost one of the n⁺⁺-type source regions 107, provided closest to the edge termination region 160. The border between the active region 150 and the border region 155 in a direction orthogonal to the direction in which the trenches 125 extend is a center of each outermost one of the trenches 125, closest to the edge termination region 160. Hatched regions in FIG. 13 are the p⁺⁺-type contact regions 106.

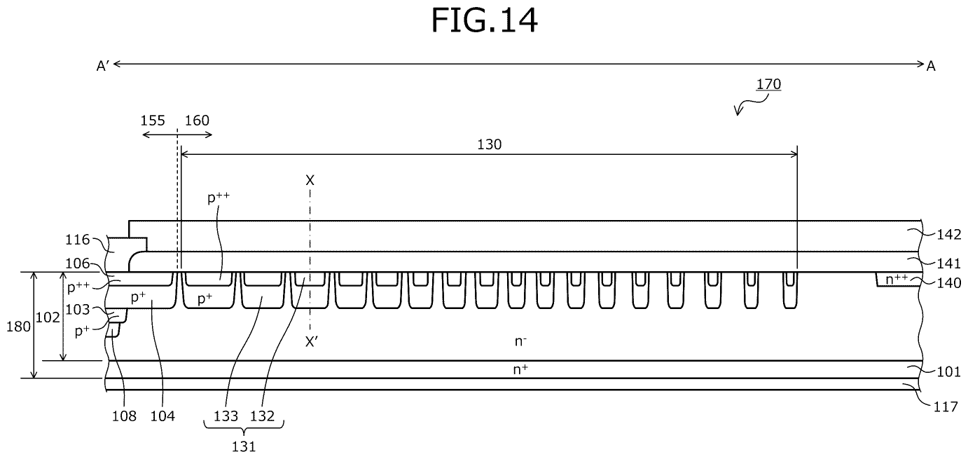

FIG. 14 is a cross-sectional view of an edge termination structure of the conventional silicon carbide semiconductor device, along cutting line A-A′. FIG. 15A is a cross-sectional view of an active structure of the conventional silicon carbide semiconductor device, along cutting line B-B′. FIG. 15B is a cross-sectional view of the active structure of the conventional silicon carbide semiconductor device, along cutting line C-C′. FIG. 15C is a cross-sectional view of the active structure of the conventional silicon carbide semiconductor device, along cutting line D-D′. In FIGS. 14 to 15C, cutting line E-E′ indicates the depth position of the plan view in FIG. 13.

FIG. 14 is a cross-sectional view along cutting line A-A′ depicted in FIG. 12 and depicts the border region 155 and the edge termination region 160. A border between the border region 155 and the edge termination region 160 is an end of an inter-trench p⁺-type subregion 104, facing the edge termination region 160. FIG. 15A is a cross-sectional view along cutting line B-B′ depicted in FIG. 13 and depicts a cross-section, in a direction orthogonal to the direction in which the trenches 125 extend, at the border between the border region 155 and the active region 150, where the p⁺⁺-type contact regions 106 are provided. FIG. 15B is a cross-sectional view along cutting line C-C′ depicted in FIG. 13 and depicts a cross-section, in a direction orthogonal to the direction in which the trenches 125 extend, at the border between the border region 155 and the active region 150, where the n⁺⁺-type source regions 107 are provided. FIG. 15C is a cross-sectional view along cutting line D-D′ depicted in FIG. 13 and depicts a cross-section, in the direction in which the trenches 125 extend, at the border between the border region 155 and the active region 150.

As depicted in FIGS. 14, 15A, 15B, and 15C, in the border region 155 of the conventional silicon carbide semiconductor device 170, an n⁺-type silicon carbide substrate 101, the n⁻-type drift region 102, trench-bottom p⁺-type subregions 103, the inter-trench p⁺-type subregions 104, the p⁺⁺-type contact regions 106, an n-type high-concentration region layer 108, gate insulating films 111, the gate electrodes 113, an interlayer insulating film 114, a barrier metal 115, the source electrode 116, a drain electrode 117, and the trenches 125 are provided. In the conventional silicon carbide semiconductor device 170, the n⁺-type silicon carbide substrate 101 and the n-type drift region 102 at an upper surface of the n⁺-type silicon carbide substrate 101 are provided. Hereinafter, the n⁺-type silicon carbide substrate and the n-type drift region 102 collectively are assumed to be a silicon carbide substrate 180.

As depicted in FIGS. 15A and 15B, in the active region 150 of the conventional silicon carbide semiconductor device 170, the n⁺-type silicon carbide substrate 101, the n-type drift region 102, the trench-bottom p⁺-type subregions 103, the inter-trench p⁺-type subregions 104, p-type base regions 105, the p⁺⁺-type contact regions 106, the n⁺⁺-type source regions 107, the n-type high-concentration region layer 108, the gate insulating films 111, the gate electrodes 113, the interlayer insulating film 114, the source electrode 116, the drain electrode 117, and the trenches 125 are provided. In the active region 150 of the conventional silicon carbide semiconductor device 170, at a surface (hereinafter, first main surface of the silicon carbide substrate 180) of the n-type drift region 102 of the silicon carbide substrate 180, the interlayer insulating film 114 and the source electrode 116 are provided.

In FIG. 15A, the active region 150 has the n-type high-concentration region layer 108 provided in a surface layer of the n⁻-type drift region 102, the p-type base regions 105 provided at an upper surface of the n-type high-concentration region layer 108, and the n⁺⁺-type source regions 107 provided at upper surfaces of the p-type base regions 105. The trenches 125 are provided from the first main surface of the silicon carbide substrate 180 (surfaces of the n⁺⁺-type source regions 107), in a direction to the n⁺-type silicon carbide substrate 101. The trenches 125 penetrate through the n⁺⁺-type source regions 107 and the p-type base regions 105 and reach the n-type high-concentration region layer 108. In the trenches 125, the gate electrodes 113 are provided via the gate insulating films 111. Between the trenches 125 that are adjacent to each other, the inter-trench p⁺-type subregions 104 and the p⁺⁺-type contact regions 106 are provided. The inter-trench p⁺-type subregions 104 are provided in contact with lower surfaces of the p⁺⁺-type contact regions 106. Side surfaces of the p⁺⁺-type contact regions 106 are in contact with the n⁺⁺-type source regions 107. Side surfaces of the inter-trench p⁺-type subregions 104 are in contact with the p-type base regions 105, the n-type high-concentration region layer 108, and the later-described trench-bottom p⁺-type subregions 103. The trench-bottom p⁺-type subregions 103 are provided underlying bottoms of the trenches 125. The trench-bottom p⁺-type subregions 103 are provided apart from the p-type base regions 105. Between the trench-bottom p⁺-type subregions 103 and the p-type base regions 105, the n-type high-concentration region layer 108 is provided. Ends of the trench-bottom p⁺-type subregions 103 are in contact with the inter-trench p⁺-type subregions 104. In FIG. 15A, in the border region 155, the n⁺⁺-type source regions 107, the inter-trench p⁺-type subregions 104, and the trench-bottom p⁺-type subregions 103 are in contact with side surfaces of the trenches 125. Further, the inter-trench p⁺-type subregions 104 are in contact with the trench-bottom p⁺-type subregions 103.

In FIG. 15B, the active region 150 being free of the inter-trench p⁺-type subregions 104 and the p⁺⁺-type contact regions 106 differs from the active region 150 depicted in FIG. 15A. In FIG. 15B, the border region 155 has a same configuration as that of the border region 155 depicted in FIG. 15A.

As depicted in FIG. 15C, in the active region 150 of the conventional silicon carbide semiconductor device 170, at the first main surface of the silicon carbide substrate 180, the p⁺⁺-type contact regions 106 and the n⁺⁺-type source regions 107 are provided alternating each other along the direction in which the trenches 125 extend. The inter-trench p⁺-type subregions 104 in contact with lower surfaces of the p⁺⁺-type contact regions 106 are provided and the p-type base regions 105 in contact with lower surfaces of the n⁺⁺-type source regions 107 are provided. The gate electrodes 113 are connected to the gate pad 112 via a polysilicon layer 115 and a gate finger (not depicted).

As depicted in FIG. 14, in the edge termination region 160 of the conventional silicon carbide semiconductor device 170, the n⁺-type silicon carbide substrate 101, the n-type drift region 102, a field oxide film 141, a polyimide film 142, the FLR structure 130, the drain electrode 117, and an n⁺⁺-type channel stopper region 140 are provided. In the edge termination region 160 of the conventional silicon carbide semiconductor device 170, the FLR structure 130 and the n⁺⁺-type channel stopper region 140 are provided at the first main surface of the silicon carbide substrate 180. In the edge termination region 160 of the conventional silicon carbide semiconductor device 170, the field oxide film 141 and the polyimide film 142 are provided on the first main surface of the silicon carbide substrate 180. At a lower surface (hereinafter, second main surface of the silicon carbide substrate 180) of the n⁺-type silicon carbide substrate 101 of the conventional silicon carbide semiconductor device 170, the drain electrode 117 is provided.

In the conventional silicon carbide semiconductor device, in the silicon carbide substrate, at the first main surface thereof, the multiple FLRs 131 of a p-type are disposed in the FLR structure 130. In a center portion of each of the FLRs 131, a high-concentration p-type FLR region 132 is provided near the surface, each of the high-concentration p-type FLR regions 132 being a shallow region with a high concentration. In each of the FLRs 131, at the surface thereof, portions between side surfaces of the high-concentration p-type FLR region 132 and side surfaces of the FLR 131, and a portion of the FLR 131 facing the n⁺-type silicon carbide substrate 101 constitute a low-concentration p-type FLR region 133 having a dopant concentration lower than that of the high-concentration p-type FLR regions 132. The high-concentration p-type FLR regions 132 suffice to be of a same depth as that of the p⁺⁺-type contact regions 106 and to have a same dopant concentration as that of the p⁺⁺-type contact regions 106.

As described, in the edge termination structure 160 that employs the FLRs 131 that are shallower than the trench-bottom p⁺-type subregions 103, the breakdown voltage is ensured by distributing electric field in the FLR regions 130 as much as possible and causing dielectric breakdown at the ends of the trench-bottom p⁺-type subregions 103.

The voltage withstanding structure of the conventional silicon carbide semiconductor device 170 has the high-concentration p-type FLR regions 132 of a same depth as that of and a same dopant concentration as that of the p⁺⁺-type contact regions 106 in the active region 150 and has the following problems. Firstly, the breakdown voltage of the edge termination region 160 decreases due to electric field concentrating at the high-concentration p-type FLR regions 132 at the surface of the silicon carbide substrate 180 and thus, due to process variation and design conditions of the active region 150, the breakdown voltage of the edge termination region 160 may be lower than the breakdown voltage of the active region 150. In this instance, in the edge termination region 160, which has an area smaller than that of the active region 150, dielectric breakdown occurs and thus, the risk of device element destruction and deterioration of peripheral components due to heat generation increases. Secondly, when charge accumulates at the surface of the edge termination region 160 due to use under high temperatures and high humidity conditions, the electric field strength at the surface of the edge termination region 160 increases, increasing the risk of discharge.

As described, with the voltage withstanding structure of the conventional silicon carbide semiconductor device 170, reduction of both manufacturing cost and variation of the breakdown voltage is impossible. In the present disclosure, the above problems are addressed by adopting a FLR structure, completing ion implantation with a single session, and enabling formation together with the p-type regions of the active region, whereby a semiconductor device having a relatively lower manufacturing cost and smaller variations in the breakdown voltage due to variations in dimensions and the edge surface charge is provided.

Embodiments of a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and will not be repeatedly described. Further, with consideration of variation in manufacturing, description indicating the same or equal may be within 5%.

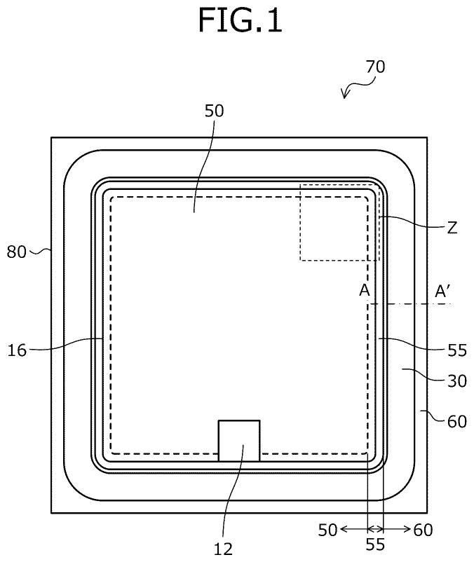

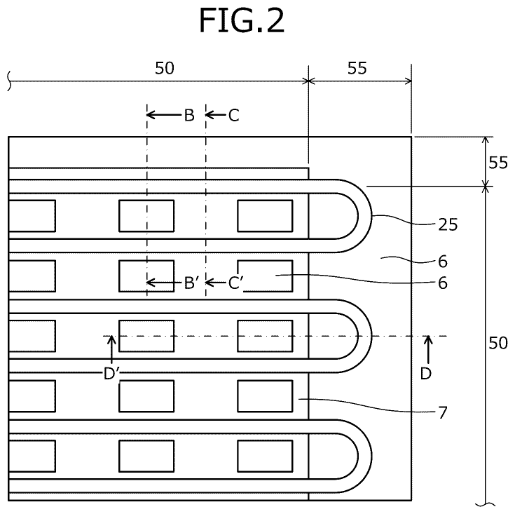

The semiconductor device according to the present disclosure contains a wide band gap semiconductor. In the embodiments, a silicon carbide semiconductor device fabricated using, for example, silicon carbide (SiC), as a wide band gap semiconductor is described taking a metal oxide semiconductor field effect transistor (MOSFET) as an example. FIG. 1 is a top view of a silicon carbide semiconductor device 70 according to an embodiment. FIG. 2 is an enlarged view of a region Z of the silicon carbide semiconductor device 70 according to the embodiment depicted in FIG. 1.

The silicon carbide semiconductor device 70 according to the embodiment depicted in FIG. 1 has an active region 50, an edge termination region 60 surrounding the active region 50 in a plan view, and a border region 55 between the active region 50 and the edge termination region 60. The active region 50 is a region through which current flows during an on-state and the edge termination region 60 is a region that relaxes electric field in an n-type drift region 2 (at a front surface thereof (first semiconductor layer)) and sustains the breakdown voltage. The border region 55 is a region connecting the active region 50 and the edge termination region 60. In the present example, a FLR structure 30 configured by multiple FLRs 31 so as to surround the border region 55 in a plan view is provided in the edge termination region 60. In the border region 55, gate wiring (not depicted) is provided and connected to a gate pad 12. Further, various sensing device elements such as for current sensing, temperature sensing, and the like may be provided. A region indicated by hatching is a source electrode 16. The source electrode 16 is provided in the active region 50 and the border region 55.

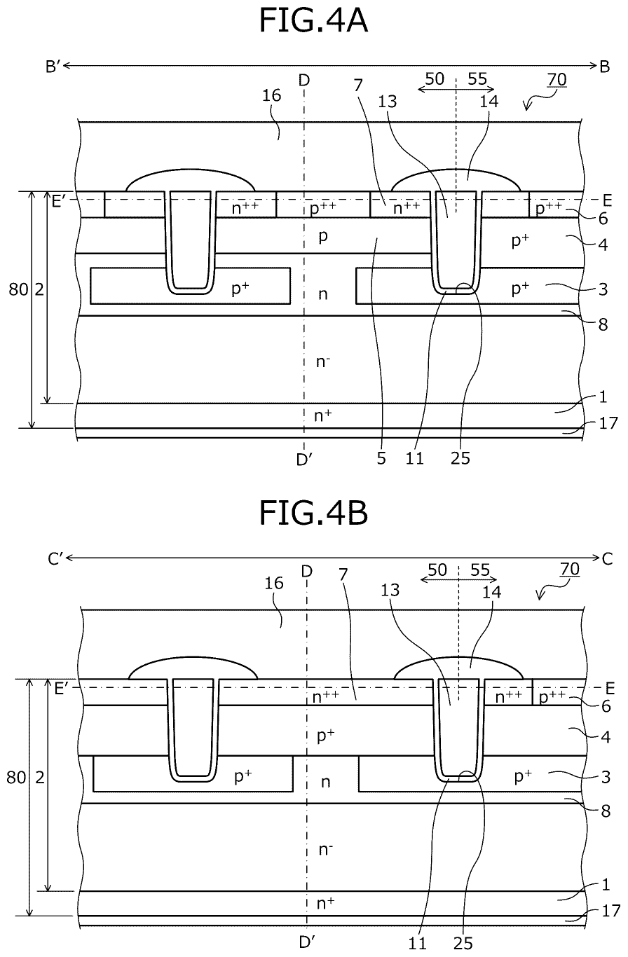

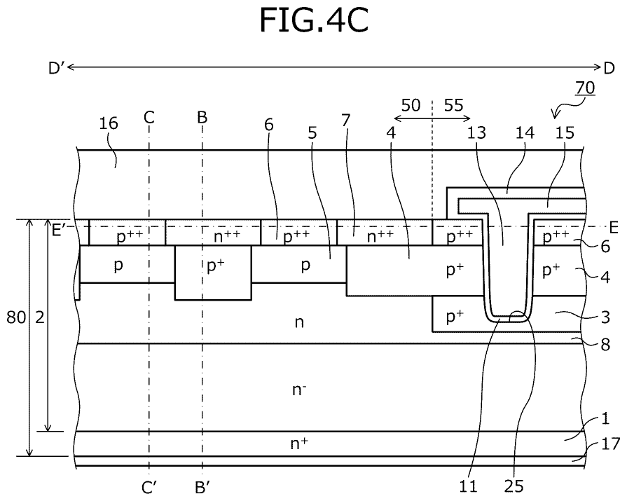

FIG. 2 is an enlarged plan view of the region Z depicted in FIG. 1, at a depth of cutting line E-E′ in later-described FIGS. 4A to 4C. In the active region 50, trenches 25 each provided in a stripe-like shape, gate electrodes 13 provided in the trenches 25 via gate insulating films (not depicted), n⁺⁺-type source regions 7, and p⁺⁺-type contact regions 6 (first semiconductor regions) are provided. A border between the active region 50 and the border region 55 in a direction in which the trenches 25 extend, for example, is an end of each outermost one of the n⁺⁺-type source regions 7, provided closest to the edge termination region 60. The border between the active region 50 and the border region 55 in a direction orthogonal to the direction in which the trenches 25 extend, for example, is a center of each outermost one of the trenches 25, closest to the edge termination region 60.

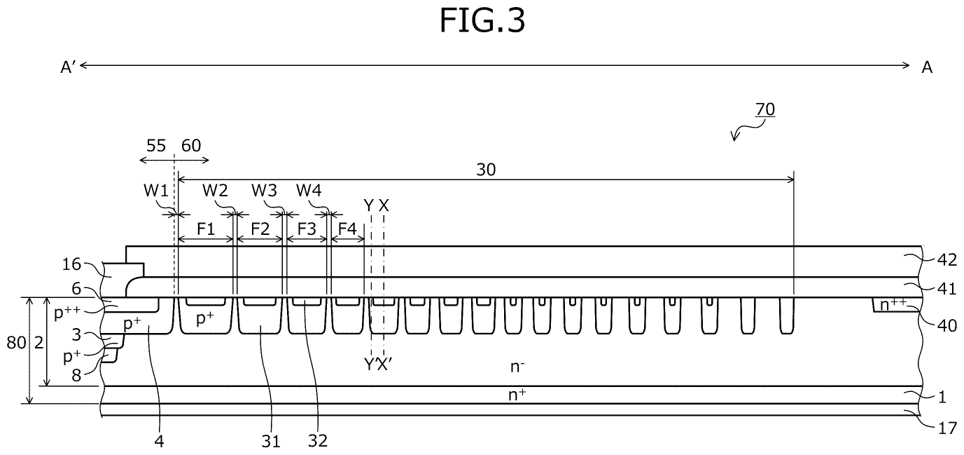

FIG. 3 is a cross-sectional view of an edge termination structure of the silicon carbide semiconductor device according to the embodiment, along cutting line A-A′. FIG. 4A is a cross-sectional view of an active structure of the silicon carbide semiconductor device according to the embodiment, along cutting line B-B′. FIG. 4B is a cross-sectional view of the active structure of the silicon carbide semiconductor device according to the embodiment, along cutting line C-C′. FIG. 4C is a cross-sectional view of the active structure of the silicon carbide semiconductor device according to the embodiment, along cutting line D-D′.

FIG. 3 is a cross-sectional view along cutting line A-A′ depicted in FIG. 1 and depicts the border region 55 and the edge termination region 60. A border between the border region 55 and the edge termination region 60 is, for example, an end of an inter-trench p⁺-type subregion 4, facing the edge termination region 60. FIG. 4A is a cross-sectional view along cutting line B-B′ depicted in FIG. 2 and depicts a cross-section (in a direction orthogonal to the direction in which the trenches 25 extend) of the border region 55 and the active region 50, where the p⁺⁺-type contact regions 6 are provided. FIG. 4B is a cross-sectional view along cutting line C-C′ depicted in FIG. 2 and depicts a cross-section (in a direction orthogonal to the direction in which the trenches 25 extend) of the border region 55 and the active region 50, where the n⁺⁺-type source regions 7 are provided. FIG. 4C is a cross-sectional view along cutting line D-D′ depicted in FIG. 2 and depicts a cross-section of the border region 55 and the active region 50, in the direction in which the trenches 25 extend.

As depicted in FIGS. 3, 4A, 4B, and 4C, in the border region 55 of the silicon carbide semiconductor device 70 according to the embodiment, an n⁺-type silicon carbide substrate 1, the n⁻-type drift region 2, trench-bottom p⁺-type subregions 3, the inter-trench p⁺-type subregions 4, the p⁺⁺-type contact regions 6, an n-type high-concentration region layer 8, gate insulating films 11, the gate electrodes 13, an interlayer insulating film 14, the source electrode 16, a drain electrode 17, and the trenches 25 are provided. In the silicon carbide semiconductor device 70 according to the embodiment, the n⁺-type silicon carbide substrate 1 and the n-type drift region 2 at an upper surface of the n⁺-type silicon carbide substrate 1 are provided. Hereinafter, the n⁺-type silicon carbide substrate 1 and the n⁻-type drift region 2 collectively are assumed to be a silicon carbide substrate 80. The n⁺-type silicon carbide substrate 1 is a silicon carbide single crystal substrate. The n⁻-type drift region 2 has a dopant concentration lower than that of the n⁺-type silicon carbide substrate 1. The dopant concentration of the n⁻-type drift region 2 is, for example, 5×10¹⁶ cm⁻³ or lower and a thickness of the n⁻-type drift region 2 is 5.0 μm or more. The n⁺-type silicon carbide substrate 1 functions as a drain region. At a back surface (second main surface of the silicon carbide substrate 80) of the n⁺-type silicon carbide substrate 1, the drain electrode 17 constituting a back electrode is provided. Further, for example, a buffer layer or the like that suppresses the growth of crystal defects from the n⁺-type silicon carbide substrate 1 may be provided between the n-type drift region 2 and the n⁺-type silicon carbide substrate 1.

As depicted in FIGS. 4A and 4B, in the active region 50 of the silicon carbide semiconductor device 70 according to the embodiment, the n⁺-type silicon carbide substrate 1, the n⁻-type drift region 2, the trench-bottom p⁺-type subregions 3, the inter-trench p⁺-type subregions 4, p-type base regions 5, the p⁺⁺-type contact regions 6, the n⁺⁺-type source regions 7, the n-type high-concentration region layer 8, the gate insulating films 11, the gate electrodes 13, the interlayer insulating film 14, the source electrode 16, the drain electrode 17, and the trenches 25 are provided. In the active region 50 of the silicon carbide semiconductor device 70 according to the embodiment, the interlayer insulating film 14 and the source electrode 16 are provided on the surface (hereinafter, first main surface of the silicon carbide substrate 80) of the n⁻-type drift region 2.

In FIG. 4A, the active region 50 has the n-type high-concentration region layer 8 provided in a surface layer of the n⁻-type drift region 2, the p-type base regions 5 provided at an upper surface of the n-type high-concentration region layer 8, and the n⁺⁺-type source regions 7 provided at upper surfaces of the p-type base regions 5. The trenches 25 are provided in the silicon carbide substrate 80, from the first main surface thereof. The trenches 25 penetrate through the n⁺⁺-type source regions 7 and the p-type base regions 5, from the first main surface of the silicon carbide substrate 80 (surfaces of the n⁺⁺-type source regions 7) and reach the n-type high-concentration region layer 8. A dopant concentration of the n-type high-concentration region layer 8 is lower than that of the n⁺-type silicon carbide substrate 1 but higher than that of the n-type drift region 2. In an instance in which the n-type high-concentration region layer 8 is omitted, the trenches 25 may be provided reaching the n-type drift region 2 from the first main surface of the silicon carbide substrate 80. Along inner walls of the trenches 25, the gate insulating films 11 are provided at the bottoms and sidewalls of the trenches 25 and the gate electrodes 13 are provided on the gate insulating films 11 in the trenches 25. The gate insulating films 11 insulate the gate electrodes 13 from the n⁻-type drift region 2. A portion of each of the gate electrodes 13 may protrude toward the source electrode 16, from the first main surface of the silicon carbide substrate 80. The trench-bottom p⁺-type subregions 3 are provided so as to underlie the bottoms of the trenches 25. Upper surfaces of the trench-bottom p⁺-type subregions 3 are apart from the p-type base regions 5. Side surfaces of the trenches 25 are in contact with the n⁺⁺-type source regions 7, the p-type base regions 5, the n-type high-concentration region layer 8, and the trench-bottom p⁺-type subregions 3. Between the trenches 25 that are adjacent to each other, the p⁺⁺-type contact regions 6 are provided sandwiched between the n⁺⁺-type source regions 7, side surfaces of the p⁺⁺-type contact regions 6 being in contact with the n⁺⁺-type source regions 7. The p⁺⁺-type contact regions 6 suffice to be provided from the first main surface of the silicon carbide substrate 80 to a same depth as that of bottom surfaces of the n⁺⁺-type source regions 7. A maximum dopant concentration of the p⁺⁺-type contact regions 6, in a region at a depth of 0.5 μm from the first main surface of the silicon carbide substrate 80, is 5×10¹⁹ cm⁻³ or higher but not more than 2×10²⁰ cm⁻³. In FIG. 4A, in the border region 55, the n⁺⁺-type source regions 7, the inter-trench p⁺-type subregions 4, and the trench-bottom p⁺-type subregions 3 are in contact with side surfaces of the trenches 25. Further, lower surfaces of the inter-trench p⁺-type subregions 4 are in contact with the trench-bottom p⁺-type subregions 3.

In FIG. 4B, the active region 50 having the inter-trench p⁺-type subregions 4 but being free of the p-type base regions 5 differs from the cross-section of the active region 50 depicted in FIG. 4A in which the p⁺⁺-type contact regions 6 are provided. In FIG. 4B, the active region 50 has the n-type high-concentration region layer 8 provided in the surface layer of the n-type drift region 2, the inter-trench p⁺-type subregions 4 provided on the upper surface of the n-type high-concentration region layer 8, and the n⁺⁺-type source regions 7 provided at upper surfaces of the inter-trench p⁺-type subregions 4. In the silicon carbide substrate 80, from the first main surface thereof, the trenches 25 are provided. The trenches 25 penetrate through the n⁺⁺-type source regions 7 and the inter-trench p⁺-type subregions 4, from the first main surface of the silicon carbide substrate 80 (surfaces of the n⁺⁺-type source regions 7) and reach the n-type high-concentration region layer 8. In an instance in which the n-type high-concentration region layer 8 is omitted, the trenches 25 may be provided so as to reach the n-type drift region 2, from the first main surface of the silicon carbide substrate 80. Along inner walls of the trenches 25, the gate insulating films 11 are provided at the bottoms and sidewalls of the trenches 25 and the gate electrodes 13 are provided on the gate insulating films 11 in the trenches 25. The gate insulating films 11 insulate the gate electrodes 13 from the n-type drift region 2. A portion of each of the gate electrodes 13 may protrude toward the source electrode 16, from the first main surface of the silicon carbide substrate 80. The trench-bottom p⁺-type subregions 3 are provided so as to underlie the bottoms of the trenches 25. Upper surfaces of the trench-bottom p⁺-type subregions 3 are in contact with the inter-trench p⁺-type subregions 4. The trench-bottom p⁺-type subregions 3 are connected to the inter-trench p⁺-type subregions 4 and are thereby electrically connected to the source electrode 16. The side surfaces of the trenches 25 are in contact with the n⁺⁺-type source regions 7, the inter-trench p⁺-type subregions 4, and the trench-bottom p⁺-type subregions 3. Between the trenches 25 that are adjacent to each other, the inter-trench p⁺-type subregions 4 and the n⁺⁺-type source regions 7 are provided. Side surfaces of the inter-trench p⁺-type subregions 4 and the n⁺⁺-type source regions 7 are in contact with the trenches 25. In FIG. 4B, the border region 55 has a same structure as that of the border region 55 in FIG. 4A.

As depicted in FIG. 4C, in the active region 50 of the silicon carbide semiconductor device 70 of the embodiment, the p⁺⁺-type contact regions 6 and the n⁺⁺-type source regions 7 are provided in the silicon carbide substrate 80, at the first main surface thereof, alternating with each other along the direction in which the trenches 25 extend. The p-type base regions 5 are provided in contact with lower surfaces of the p⁺⁺-type contact regions 6 while the inter-trench p⁺-type subregions 4 and the p-type base regions 5 are provided in contact with lower surfaces of the n⁺⁺-type source regions 7. Lower surfaces of the inter-trench p⁺-type subregions 4 are provided at a depth position deeper than are lower surfaces of the p-type base regions 5. In the border region 55, the gate electrodes 13 are connected to a polysilicon layer 15. The polysilicon layer 15 is connected to the gate pad 12 via a gate finger (not depicted).

The trench-bottom p⁺-type subregions 3 and the inter-trench p⁺-type subregions 4 are fixed to the potential of the source electrode 16, are depleted (or cause the n-type high-concentration region layer 8 to deplete or both) when the MOSFET (the silicon carbide semiconductor device 70) is off, and have a function of relaxing electric field applied to the gate insulating films 11.

Further, a peak of the dopant concentration of the trench-bottom p⁺-type subregions 3 is in a region at a depth of 1.0 μm or more from the first main surface of the silicon carbide substrate 80 and preferably, the maximum dopant concentration may be higher than a peak of the dopant concentration of later-described FLRs 31 (second semiconductor regions). Further, in a cross-section of a region forming both the trench-bottom p⁺-type subregions 3 and the inter-trench p⁺-type subregions 4 of the active region 50 (FIG. 4A), overlap of the dopant concentrations of the trench-bottom p⁺-type subregions 3 and the inter-trench p⁺-type subregions 4 in a region of a depth from the peak of the dopant concentration of the FLRs 31 to the peak of the dopant concentration of the trench-bottom p⁺-type subregions 3 preferably may always be higher than the dopant concentration of the n-type drift region 2.

Further, as depicted in FIGS. 3, 4A, 4B, and 4C, the trench-bottom p⁺-type subregions 3, the inter-trench p⁺-type subregions 4, and the p⁺⁺-type contact regions 6 extend from the end of the active region 50 to the border region 55. As depicted in FIG. 3, in the border region 55, ends of the trench-bottom p⁺-type subregions 3 are provided 3.0 μm or more closer to the active region 50 than are the ends of the inter-trench p⁺-type subregions 4. Furthermore, in the border region 55, the ends of the p⁺⁺-type contact regions 6 are provided 1.0 μm or more closer to the active region 50 than are the inter-trench p⁺-type subregions 4.

The interlayer insulating film 14 is provided in an entire area of the first main surface of the silicon carbide substrate 80, so as to cover the gate electrodes 13 embedded in the trenches 25. The source electrode 16 is in contact with the n⁺⁺-type source regions 7 and the p⁺⁺-type contact regions 6 via contact holes opened in the interlayer insulating film 14. The source electrode 16 is electrically insulated from the gate electrodes 13 by the interlayer insulating film 14. A source electrode pad (not depicted) is provided on the source electrode 16. Between the source electrode 16 and the interlayer insulating film 14, for example, a barrier metal (not depicted) for preventing diffusion of metal atoms from the source electrode 16 to the gate electrodes 13 may be provided. A polyimide film 42 functioning as a protective film is provided at the surface of the silicon carbide semiconductor device 70. In FIGS. 4A and 4B, in the active region 50, while only two MOS gate (metal-oxide-semiconductor insulated gate) structures are depicted, further MOS gate structures suffice to be disposed in parallel.

As depicted in FIG. 3, in the edge termination region 60 of the semiconductor device according to the embodiment, the FLR structure 30 is provided. Further, an n⁺⁺-type channel stopper region 40 functioning as a channel stopper is provided at the surface (the first main surface of the silicon carbide substrate 80) of the n⁻-type drift region 2 outside (closer to a chip end than is) the FLR structure 30. The n⁺⁺-type channel stopper region 40 may be a p⁺⁺-type. Pn junctions between the FLR structure 30 and the n⁻-type drift region 2 sustain a high breakdown voltage in a lateral direction. The edge termination region 60 is covered by a field oxide film 41 and on the field oxide film 41, a HTO film (not depicted), an interlayer insulating film (not depicted), and the polyimide film 42 are sequentially stacked.

In the FLR structure 30, the multiple FLRs (second semiconductor regions of a second conductivity type) 31 of a p-type are disposed in the silicon carbide substrate 80, at the first main surface thereof. The FLRs 31 are provided in the surface layer of the n⁻-type drift region 2. In surface layers of the FLRs 31, intra-FLR n-type regions (third semiconductor regions of the first conductivity type) 32 are provided. At surfaces of the FLRs 31 and the intra-FLR n-type regions 32, the first main surface of the silicon carbide substrate 180 is exposed. The FLRs 31 and the intra-FLR n-type regions 32 are provided in ring shapes so as to surround the active region 50, in a plan view. The FLRs 31 are provided apart from each other and respective widths thereof are smaller the closer the FLRs 31 are to the edge termination region 60. Respective widths of the intra-FLR n⁻-type regions 32 are smaller the closer the intra-FLR n⁻-type regions 32 are to the ends of the edge termination region 60. The FLRs 31 provided relatively closer to the chip end in the FLR structure 30 may be free of the intra-FLR n⁻-type regions 32. Each of the FLRs 31 in which any one of the intra-FLR n-type regions 32 is provided has a center region that is in contact with a lower surface of the any one of the intra-FLR n⁻-type regions 32 and p-type regions that are at each side surface of the center region and in contact with each side surface of the any one of the intra-FLR n-type regions 32 (hereinafter, the p-type regions of the ends of the FLRs 31). The intra-FLR n-type regions 32 may have a doping concentration distribution that is a same as that of the original n⁻-type drift region 2 free of ion implantation. Preferably, the intra-FLR n-type regions 32 may be provided by implanting an n-type dopant in the p-type FLRs 31.

The intra-FLR n⁻-type regions 32 are in contact with the first main surface of the silicon carbide substrate 80 (surface of the n⁻-type drift region 2). A depth from the first main surface of the silicon carbide substrate 80 to lower surfaces of the intra-FLR n-type regions 32 is within a range of ⅕ or more but not more than ½ of the depth from the first main surface of the silicon carbide substrate 80 to lower surfaces of the FLRs 31. The p-type regions of the ends of the FLRs 31 are in contact with the surface of the n-type drift region 2 assuredly create a depletion layer. Preferably, a dopant concentration of the intra-FLR n⁻-type regions 32 may be lower than a dopant concentration of the n-type drift region 2. The intra-FLR n⁻-type regions 32 may be provided by implanting an n-type dopant in the p-type FLRs 31. In this instance, the dopant concentration of the intra-FLR n-type regions 32 may be higher than that of the n-type drift region 2. In the cross-section along cutting line A-A′ in FIG. 3, a direction from the first main surface of the silicon carbide substrate 80 to the drain electrode 17 is assumed to be a depth direction while a direction from the border region 55 to outside the edge termination region 60 is assumed to be a width direction. Here, a width of each of the intra-FLR n⁻-type regions is assumed to be a width (in the width direction) of each of the intra-FLR n⁻-type regions 32 in contact with the first main surface of the silicon carbide substrate 80. Further, both ends of each of the intra-FLR n⁻-type regions 32, in the width direction, are assumed to be both ends of surfaces of each of the intra-FLR n⁻-type regions 32 in contact with the first main surface of the silicon carbide substrate 80. Further, a depth of the intra-FLR n⁻-type regions 32, in the depth direction, is assumed to be from the first main surface of the silicon carbide substrate 80 to the lower surfaces of the intra-FLR n-type regions 32. At a center of the depth of the intra-FLR n⁻-type regions 32 and at a center of the width of the intra-FLR n-type regions 32, preferably, the dopant concentration of the intra-FLR n⁻-type regions 32 may be 1/10 times or more but not more than 10 times the dopant concentration of the n-type drift region. At the center of the depth of the intra-FLR n⁻-type regions 32 and at the center of the width of the intra-FLR n-type regions 32, the dopant concentration of the intra-FLR n⁻-type regions 32 may be 1×10¹⁵ cm⁻³ or higher but not more than 1×10¹⁷ cm³. The dopant concentration of the intra-FLR n-type regions 32, at a predetermined location, may be 1/10 times or more but not more than 10 times the dopant concentration of the n⁻-type drift region 2. Preferably, the dopant concentration of the intra-FLR n⁻-type regions 32 may be 1×10¹⁵ cm³ or higher but not more than 1×10¹⁷ cm³ at the predetermine location. Here, in an instance of 100% for the center of the depth of the intra-FLR n-type regions 32 and for the width of the intra-FLR n-type regions 32, the predetermined location is a location 20% inward from each of the ends of the intra-FLR n-type regions 32. In the intra-FLR n-type regions 32, the dopant concentration at the surfaces of the intra-FLR n⁻-type regions 32 (the first main surface of the silicon carbide substrate 80) may be higher than that at the center depth of the intra-FLR n⁻-type regions 32. The FLRs 31 and the intra-FLR n⁻-type regions 32 have a floating potential and are not electrically connected to any of the device electrodes. As described, at the surface of the center region of each of the FLRs 31, the intra-FLR n⁻-type regions 32 extend and both ends of each of the FLRs 31 are connected to the surface of the n-type drift region 2. However, among the multiple FLRs 31, those with a width of 1.5 μm or less are free of the intra-FLR n-type regions 32.

Further, the intra-FLR n⁻-type regions 32 have to be provided in at least innermost ones of the FLRs 31, closest to the active region 5. Preferably, the intra-FLR n⁻-type regions 32 may be provided in ¼ or more of the FLRs 31 from the innermost ones of the FLRs 31 closest to the active region 50 while more preferably, the intra-FLR n-type regions 32 may be provided in ½ or more of the FLRs 31, and most preferably, the intra-FLR n⁻-type regions 32 may be provided in ⅔ or more of the FLRs 31. Further, the width of each of the intra-FLR n-type regions 32, preferably, may be 50% or more but not more than 80% of the width of each of the FLRs 31.

The p-type regions of the ends of the FLRs 31 are in contact with the surface of the n-type drift region 2. Preferably, the width of each of the p-type regions of the ends of the FLRs 31 may be 10% or more but not more than 25% of the width of each of the FLRs 31 In other words, the intra-FLR n-type regions 32 are apart from the ends of the FLRs 31 by a distance that is 10% or more but not more than 25% of the width of each of the FLRs 31. For example, the width of each of the p-type regions of the ends of the FLRs 31 is 0.5 μm or more but not more than 1.5 μm.

The FLRs 31 are formed under the same ion implantation conditions as those for the inter-trench p⁺-type subregions 4 of the active region 50 and the border region 55 and thus, may be of a same depth as that of the inter-trench p⁺-type subregions 4 and the concentration distribution in the depth direction is a same as that of the inter-trench p⁺-type subregions 4. Further, the FLRs 31 are shallower than the trench-bottom p⁺-type subregions 3 of the active region 50 and the border region 55.

The FLRs 31 are disposed in descending order of width in a direction from the active region 50 to the chip end while intervals therebetween are in ascending order. For example, as depicted in FIG. 3, in an instance in which 17 of the FLRs 31 are disposed (F1 to F17, in FIG. 3, only F1 to F4 are depicted), the widths of the FLRs 31, the intervals (W2 to W17, in FIG. 3, only W2 to W4 are depicted) between the FLRs 31, and an interval W1 between the p⁺⁺-type contact region 6 and the innermost one (F1) of the FLRs 31, closest to the active region 50 are indicated in Table 1. In Table 1, values are in units of μm.

TABLE 1

| | W1 | W2 | W3 | W4 | N5 | W6 | W7 | W8 | W9 | W10 | W11 | W12 | W13 | W14 | W15 | W16 | W17 |
|---|---|---|---|---|---|---|---|---|---|---|---|---|---|---|---|---|---|
| INTERVAL | 1.00 | 1.05 | 1.10 | 1.15 | 1.25 | 1.35 | 1.50 | 1.65 | 1.80 | 2.00 | 2.20 | 2.45 | 2.70 | 2.95 | 3.25 | 3.60 | 4.00 |
| | F1 | F2 | F3 | F4 | F5 | F6 | F7 | F8 | F9 | F10 | F11 | F12 | F13 | F14 | F15 | F16 | F17 |
| WIDTH | 7.0 | 6.0 | 5.0 | 4.0 | 4.0 | 3.0 | 3.0 | 3.0 | 2.0 | 2.0 | 2.0 | 2.0 | 2.0 | 2.0 | 2.0 | 1.5 | 1.5 |

As depicted in Table 1, respective widths F1 to F15 of the FLRs 31 are greater than 1.5 μm and the intra-FLR n-type regions 32 are provided. On the other hand, respective widths of F16 and F17 of the FLRs 31 are 1.5 μm or less and the intra-FLR n⁻-type regions 32 are not provided. The respective widths of the FLRs 31 at the uppermost surface of the n⁻-type drift region 2 is 6.0 μm or more closest to the active region 50 and 2.0 μm or less near the outer periphery of the chip, and the widths of the FLRs 31 are not more than the width of an adjacent one of the FLRs 31 closer to the active region 50. As depicted in Table 1, at an uppermost surface of the n⁻-type drift region 2, an interval between the side surfaces of an adjacent two of the FLRs 31 closest to the active region 50 is 2.0 μm or less and 3.0 μm or more near the outer periphery of the chip. Intervals of the FLRs 31 are greater than or equal to intervals between adjacent ones of the FLRs 31 near the active region 50. The number of FLRs may be 10 or more, preferably. In the silicon carbide semiconductor device in Table 1, while the intervals between the centers of adjacent FLRs 31 are not constant, the width of the FLRs 31 and the spacing between the side surfaces of adjacent FLRs 31 may be adjusted so that the spacing between the centers of the FLRs 31 is constant.

In the embodiment, the p-type FLRs 31 sustain the edge breakdown voltage and disposal of the intra-FLR n⁻-type regions 32 in surface layers of the FLRs 31 relaxes the concentration of electric field. As a result, the breakdown voltage is further improved as compared to the conventional structure, the risk of dielectric breakdown at the edge is reduced, and increases in surface electric field strength when charge accumulates at the edge surface is suppressed and the risk of discharge may be suppressed. Further, in the formation of the FLRs 31 and the intra-FLR n-type regions 32, SiC etching and high-acceleration ion implantation are not used, whereby manufacturing costs may be reduced.

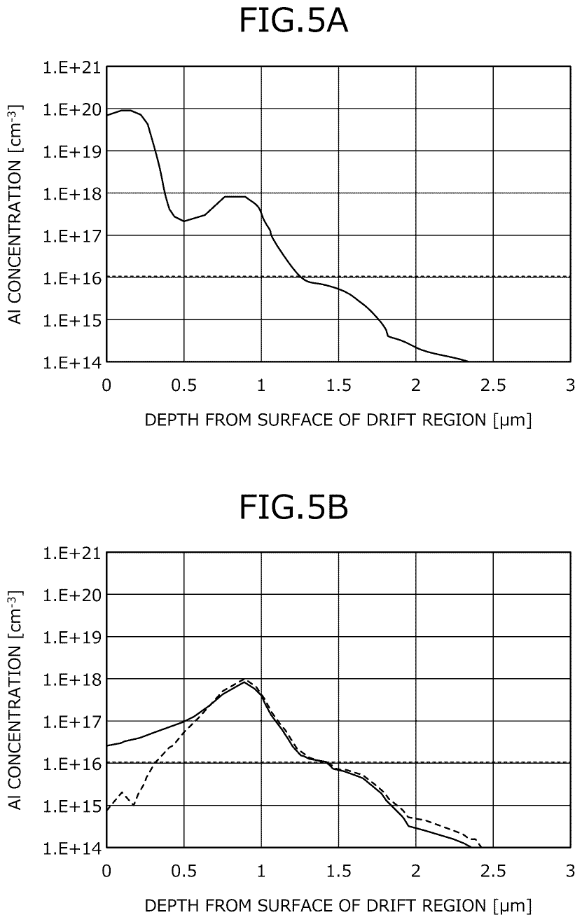

FIG. 5A is graph depicting distribution of the AI concentration of the FLRs of the conventional silicon carbide semiconductor device, in the depth direction. FIG. 5B is a graph depicting distribution of the AI concentration in the FLRs of the silicon carbide semiconductor device according to the embodiment, in the depth direction. In FIGS. 5A and 5B, the vertical axis indicates dopant (herein, aluminum (Al)) concentration of the FLRs 31 in units of cm⁻³. The horizontal axis indicates depth from the surface of the n-type drift region 2 in units of μm. In FIGS. 5A and 5B, as the dopant concentration of the n⁻-type drift region 2, for example, 1×10¹⁶ cm³ is indicated by a dashed line.

FIG. 5A depicts the dopant concentration in a cross-section along cutting line X-X′ in FIG. 14; in FIG. 5B, a dotted line depicts the dopant concentration in a cross-section along cutting line X-X′ in FIG. 3 and a solid line depicts the dopant concentration in a cross-section along cutting line Y-Y′ in FIG. 3. As indicated by the dotted line in FIG. 5B, in the intra-FLR n⁻-type regions 32 provided in the surface layers of the FLRs 31 and the center regions of the FLRs 31 in contact with the lower surfaces of the intra-FLR n⁻-type regions 32, the concentration of AI at the surface of the n⁻-type drift region 2 is lower than the dopant concentration of the n⁻-type drift region 2 and is an n-type region. As indicated by the solid line in FIG. 5B, in the p-type regions of the ends of the FLRs 31, the concentration of AI at the surface of the n⁻-type drift region 2 is higher than the dopant concentration of the n⁻-type drift region 2 and is a p-type.

Further, as depicted in FIG. 5B, the dopant concentration in the FLRs 31 exhibits a distribution having one peak in the depth direction. The peak of the dopant concentration is present within a regional range of a depth of 0.5 μm to 1.5 μm from the surface of the n⁻-type drift region 2. A maximum value of the dopant concentration is in a range of 5×10¹⁷ cm³ to 2×10¹⁸ cm³. A deepest point of the FLRs 31 is present within a regional range of depth of 1.0 μm to 2.0 μm. Further, a peak of the dopant concentration in the FLRs 31 may be a maximum value within a range ½ to ¾ of the distance from the surface of the n-type drift region 2 to the lower surfaces of the FLRs 31.

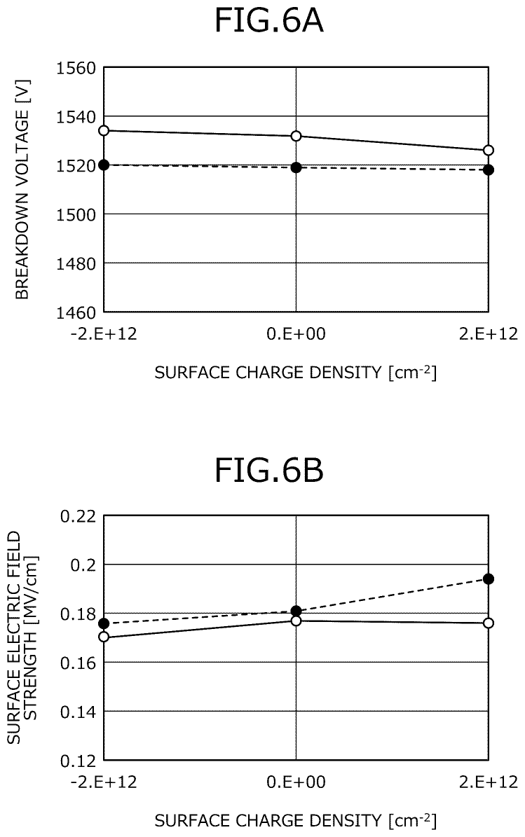

FIG. 6A is a graph depicting the edge breakdown voltage of the conventional silicon carbide semiconductor device and the silicon carbide semiconductor device according to the embodiment. FIG. 6B is a graph showing edge surface horizontal electric field strength of the conventional silicon carbide semiconductor device and the silicon carbide semiconductor device according to the embodiment. In FIG. 6A, the vertical axis indicates the breakdown voltage in units of V. The horizontal axis indicates charge density of the surface of the n⁻-type drift region 2 in units of cm². In FIG. 6B, the vertical axis indicates surface charge strength in units of MV/cm. The horizontal axis indicates charge density of the surface of the n-type drift region 2 in units of cm⁻².

In FIGS. 6A and 6B, a solid line connecting “∘” indicates simulation results for the silicon carbide semiconductor device according to the embodiment while a dotted line connecting “•” indicating simulation results for the conventional silicon carbide semiconductor device. As depicted in FIG. 6A, in the silicon carbide semiconductor device according to the embodiment, the breakdown voltage is higher than that of the conventional silicon carbide semiconductor device regardless of the value of the surface charge density. As depicted in FIG. 6B, in the silicon carbide semiconductor device according to the embodiment, the electric field strength at the edge surface is lower than that of the conventional silicon carbide semiconductor device and the risk of discharge may be further reduced. In particular, increases in the electric field in an instance in which the surface charge is applied may be suppressed in the embodiment.

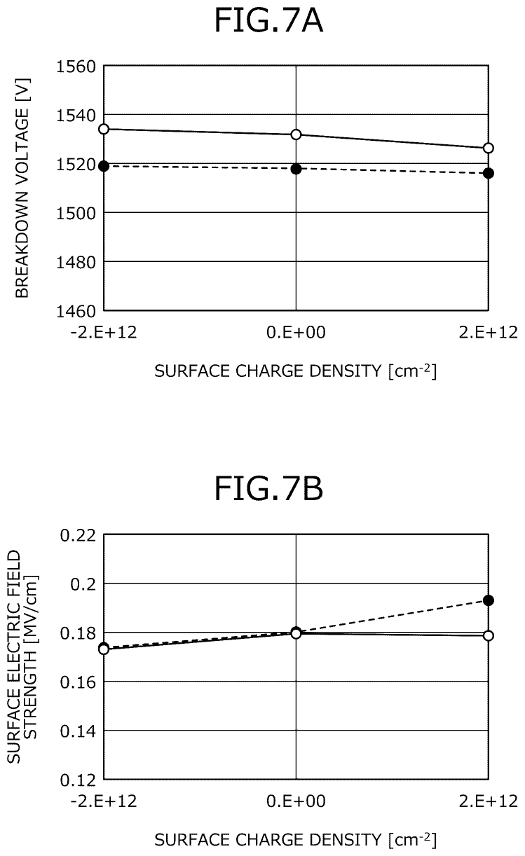

FIGS. 7A, 7B, 8A, 8B, 9A, 9B, 10A, and 10B are graphs depicting variation of the edge breakdown voltage due to variation of the dose of the FLRs 31 and variations in dimensions of the FLRs 31 of the silicon carbide semiconductor device. In FIGS. 7A to 10B, a solid line connecting “∘” indicates simulation results for the silicon carbide semiconductor device according to the embodiment while a dotted line connecting “•” indicates simulation results for the conventional silicon carbide semiconductor device. In FIGS. 7A, 8A, 9A, and 10A, the vertical axis indicates the breakdown voltage in units of V. The horizontal axis indicates the charge density of the surface of the n⁻-type drift region 2 in units of cm⁻². In FIGS. 7B, 8B, 9B, and 10B, the vertical axis indicates the surface charge strength in units of MV/cm. The horizontal axis indicates charge density of the surface of the n⁻-type drift region 2 in units of cm⁻².

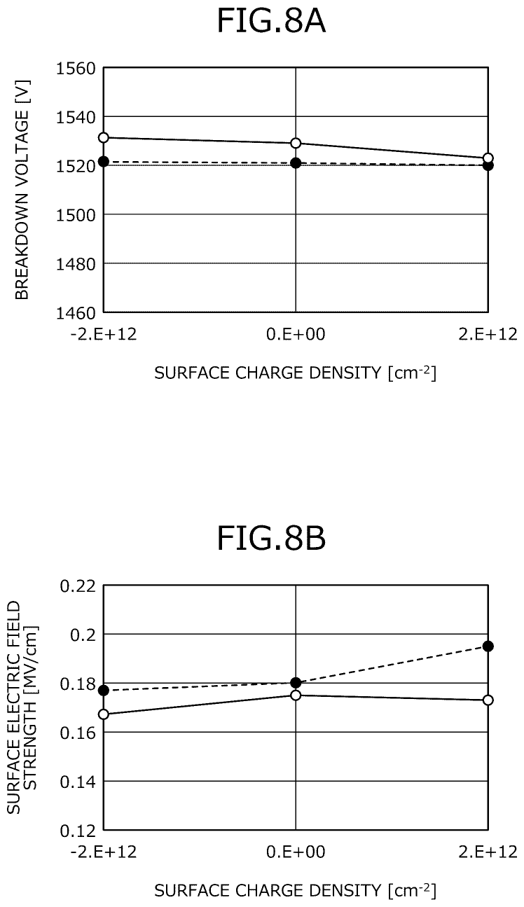

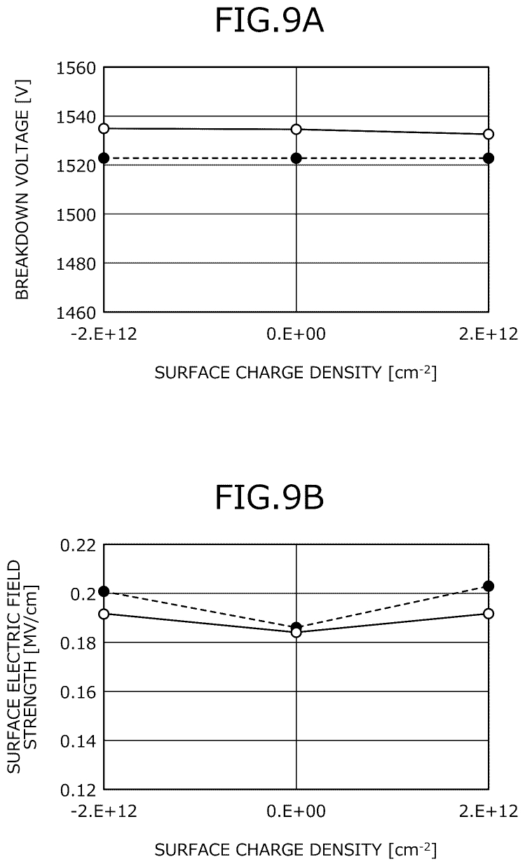

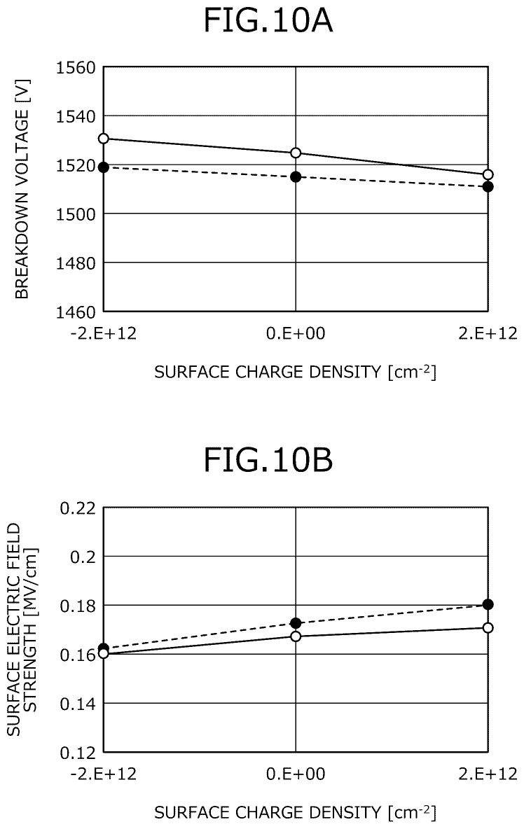

FIG. 7A is a graph depicting the edge breakdown voltage in an instance in which the doses of the FLRs 31 and the FLRs 131 of the conventional silicon carbide semiconductor device and the silicon carbide semiconductor device according to the embodiment are each +10%. FIG. 7B is a graph depicting edge-surface horizontal electric field strength in an instance in which the doses of the FLRs 31, the FLRs 131 of the conventional silicon carbide semiconductor device and the silicon carbide semiconductor device according to the embodiment are each +10%. FIG. 8A is a graph depicting the edge breakdown voltage in an instance in which the doses of the FLRs 31 and the FLRs 131 of the conventional silicon carbide semiconductor device and the silicon carbide semiconductor device according to the embodiment are each −10%. FIG. 8B is a graph depicting edge-surface horizontal electric field strength in an instance in which the doses of the FLRs 31, the FLRs 131 of the conventional silicon carbide semiconductor device and the silicon carbide semiconductor device according to the embodiment are each −10%. FIG. 9A is a graph depicting the edge breakdown voltage in an instance in which the widths of the FLRs 31 and the FLRs 131 of the conventional silicon carbide semiconductor device and the silicon carbide semiconductor device according to the embodiment are each increased 0.3 μm. FIG. 9B is a graph depicting edge-surface horizontal electric field strength in an instance in which the widths of the FLRs 31, the FLRs 131 of the conventional silicon carbide semiconductor device and the silicon carbide semiconductor device according to the embodiment are each increased 0.3 μm. FIG. 10A is a graph depicting the edge breakdown voltage in an instance in which the widths of the FLRs 31 and the FLRs 131 of the conventional silicon carbide semiconductor device and the silicon carbide semiconductor device according to the embodiment are each decreased 0.3 μm. FIG. 10B is a graph depicting edge-surface horizontal electric field strength in an instance in which the widths of the FLRs 31, the FLRs 131 of the conventional silicon carbide semiconductor device and the silicon carbide semiconductor device according to the embodiment are each decreased 0.3 μm.

As depicted in FIGS. 7A, 8A, 9A, and 10A, even when the dose (±10%) and the width (±0.3 μm) of the FLRs 31 vary, the breakdown voltage of the silicon carbide semiconductor device according to the embodiment is higher than that of the conventional silicon carbide semiconductor device. As depicted in FIGS. 7B, 8B, 9B, and 10B, even when the dose (±10%) and the width (±0.3 μm) of the FLRs 31 vary, in the silicon carbide semiconductor device according to the embodiment, electric field strength at the edge surface is lower than that in the conventional silicon carbide semiconductor device and the risk of discharge may be reduced. In particular, in the embodiment, increases in electric field when surface charge is applied may be suppressed.

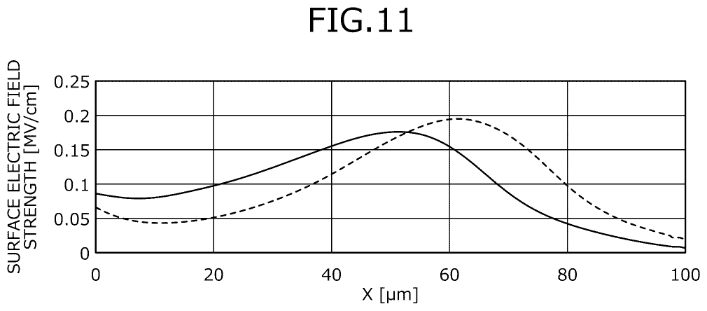

FIG. 11 is a graph depicting edge-surface electric field distribution in the conventional silicon carbide semiconductor device and the silicon carbide semiconductor device according to the embodiment. In FIG. 11, a solid line indicates simulation results for the silicon carbide semiconductor device according to the embodiment while a dotted line indicates simulation results for the conventional silicon carbide semiconductor device. In FIG. 11, the vertical axis indicates surface charge strength of the polyimide film 42 in units of MV/cm. The horizontal axis indicates a distance X from an end of the polyimide film 42 closest to the active region 50, in the edge termination region 60, in units of μm.

FIG. 11 depicts electric field distribution in the edge termination region 60 in an instance in which positive charge (2.0×10¹² cm⁻²) accumulates at the surface of the n-type drift region 2. As depicted in FIG. 11, in the silicon carbide semiconductor device according to the embodiment, electric field distribution at the surface of the edge termination region 60 is more level and the peak electric field strength is lower than that in the conventional silicon carbide semiconductor device.

Further, in a method of manufacturing the semiconductor device according to the embodiment, for example, in the n-type drift region 2, when the FLRs 31 are formed by ion implantation, the intra-FLR n⁻-type regions 32 may be formed by changing the mask so that ions are not implanted at the surface of the n-type drift region 2 of the center regions of the FLRs 31. Similar to an instance in which a MOSFET of a 1200V breakdown voltage class is fabricated, for example, another structure may be fabricated.

As described, according to the embodiment, the p-type FLRs ensure the edge breakdown voltage and disposal of the intra-FLR n⁻-type regions that are portions of the n-type drift region left at the surface of the center regions of the FLRs relaxes the concentration of electric field. As a result, the breakdown voltage is further improved as compared to the conventional structure, the risk of dielectric breakdown at the edge is reduced, and increases in surface electric field strength when charge accumulates at the edge surface is suppressed and the risk of discharge may be suppressed. Further, in the formation of the FLR and the intra-FLR n-type regions, SiC etching and high-acceleration ion implantation are not used, whereby manufacturing costs may be reduced.

In the foregoing, in the present disclosure, various modifications within a range not departing from the spirit of the disclosure are possible and in the described embodiments, for example, dimensions, dopant concentrations, etc. of regions may be variously set according to necessary specifications. Further, in the described embodiments, while an instance in which silicon carbide is used as a wide band gap semiconductor is described as an example, a wide band gap semiconductor other than silicon carbide such as, for example, gallium nitride (GaN) may be adopted. Further, in the embodiments, while the first conductivity type is assumed to an n-type and the second conductivity type is assumed to be a p-type, the present disclosure is similarly implemented when the first conductivity type is a p-type and the second conductivity type is an n-type.

According to the disclosure above, provision of the third semiconductor regions (intra-FLR n⁻-type regions) that are portions of the first semiconductor layer (n⁻-type drift region) left at the surface of the second semiconductor regions (FLR) relaxes concentration of electric field. As a result, the breakdown voltage is further improved as compared to the conventional structure, the risk of dielectric breakdown at the edge is reduced, and increases in surface electric field strength when charge accumulates at the edge surface is suppressed and the risk of discharge may be suppressed. Further, in the formation of the FLR and the intra-FLR n-type regions, SiC etching and high-acceleration ion implantation are not used, whereby manufacturing costs may be reduced.

The semiconductor device according to the present disclosure achieves an effect in that variation of the breakdown voltage due to variations in dimensions and edge surface charge may be reduced by the FLR structure.

As described, the semiconductor device according to the present disclosure is useful for power semiconductor devices used in power converting equipment such as inverters, power source devices of various types of industrial machines, igniters of automobiles, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having:
an active region through which a main current flows, and
a termination region surrounding a periphery of the active region in a plan view of the semiconductor device;
a first semiconductor layer of the first conductivity type, provided on the semiconductor substrate in both the active region and the termination region, the first semiconductor layer having a dopant concentration lower than a dopant concentration of the semiconductor substrate, the first semiconductor layer having a first surface and a second surface opposite to each other, the second surface facing the semiconductor substrate;
a first semiconductor region of a second conductivity type, provided in the active region at the first surface of the first semiconductor layer;
a plurality of second semiconductor regions of the second conductivity type, provided in the termination region at the first surface of the first semiconductor layer, the plurality of second semiconductor regions being formed at intervals and each in a ring-shape surrounding the first semiconductor region in the plan view; and
a plurality of third semiconductor regions of the first conductivity type, respectively provided in a subset of the plurality of second semiconductor regions adjacent to an end of the first semiconductor region, each third semiconductor region being provided at a surface of the respective second semiconductor region and being at a center thereof in the plan view.

2. The semiconductor device according to claim 1, wherein in a depth direction of the semiconductor device,
a depth of each of the plurality of third semiconductor regions is within a range of ⅕ or more but not more than ½ of a depth of the respective second semiconductor region.

3. The semiconductor device according to claim 1, wherein in a width direction of the semiconductor device,
each of the plurality of third semiconductor regions is apart from the respective second semiconductor region by 10% or more but not more than 25% of a width of the respective second semiconductor region.

4. The semiconductor device according to claim 1, wherein
a width of each of the plurality of third semiconductor regions is 50% or more but not more than 80% of a width of the respective second semiconductor region.

5. The semiconductor device according to claim 1, wherein
each of the plurality of third semiconductor regions has a dopant concentration that is 1/10 times or more but not more than 10 times the dopant concentration of the first semiconductor layer at a predetermined position.

6. The semiconductor device according to claim 5, wherein
the predetermined position of said each third semiconductor region includes:
a center of said each third semiconductor region in a depth direction of the semiconductor device, and
a center of said each third semiconductor region in a width direction of the semiconductor device.

7. The semiconductor device according to claim 5, wherein
the predetermined position of said each third semiconductor region is a region 20% inward of said each third semiconductor region when a width thereof is 100%.

8. The semiconductor device according to claim 1, wherein
a dopant concentration of each of the plurality of third semiconductor regions is higher at a surface thereof than at a center thereof in a depth direction of the semiconductor device.

9. The semiconductor device according to claim 1, wherein
the subset of the plurality of second semiconductor regions are closest to the active region among the plurality of second semiconductor regions.

10. The semiconductor device according to claim 1, wherein
the plurality of third semiconductor regions is provided in ¼ or more of the plurality of second semiconductor regions closest to the active region.

11. The semiconductor device according to claim 1, wherein
of the plurality of second semiconductor regions, ones having a width of 1.5 μm or less are free of the plurality of third semiconductor regions.

12. The semiconductor device according to claim 1, wherein
the plurality of second semiconductor regions is provided at a depth of 1.0 μm or more but not more than 2.0 μm from the first surface of the first semiconductor layer.

13. The semiconductor device according to claim 1, wherein
the plurality of second semiconductor regions has a dopant concentration with a maximum value that, in a depth direction of the semiconductor device, is within a range of ½ or more but not more than ¾ of a depth of the plurality of second semiconductor regions from the first surface of the first semiconductor layer.

14. The semiconductor device according to claim 1, wherein
the plurality of second semiconductor regions has a floating potential without being electrically connected to an electrode of the semiconductor device.
